(19) United States
(12) Patent Application Publication
(10) Pub. No.: US 2026/0076145 A1
(43) Pub. Date: Mar. 12, 2026

(54) CARRIER STORAGE APPARATUS, SUBSTRATE PROCESSING APPARATUS, AND CARRIER TRANSFER METHOD

(71) Applicant: Tokyo Electron Limited, Tokyo (JP)

(72) Inventors: Junichi SATO, Oshu City (JP); Tatsuya HANAKI, Oshu City (JP); Eiki FUJII, Oshu City (JP)

(21) Appl. No.: 19/252,312

(22) Filed: Jun. 27, 2025

(30) Foreign Application Priority Data
Jul. 4, 2024 (JP) 2024-108007

(51) Int. Cl. H01L 21/677; B25J 11/00; B65G 1/06; H01L 21/687

(52) U.S. Cl. CPC H10P 72/3404; B25J 11/0095; B65G 1/06; H10P 72/7602; B65G 2201/0297

(57) ABSTRACT

A carrier storage apparatus includes: a transfer mechanism; a first storage shelf group provided closer to a negative side of a first horizontal axis than the transfer mechanism, and including first storage shelves; a second storage shelf group provided closer to a positive side of the first horizontal axis than the transfer mechanism, and including second storage shelves; and a third storage shelf group provided closer to a positive or negative side of a second horizontal axis than the transfer mechanism, and including third storage shelves, wherein the second storage shelves are arranged in two or more columns along the second horizontal axis and in two or more stages along a vertical axis, wherein the third storage shelves are arranged in two or more stages along the vertical axis, and wherein the transfer mechanism is configured to transfer a carrier to the first to third storage shelves.

### CROSS-REFERENCE TO RELATED APPLICATION

This application is based upon and claims the benefit of priority from Japanese Patent Application No. 2024-108007, filed on Jul. 4, 2024, the entire contents of which are incorporated herein by reference.

### TECHNICAL FIELD

The present disclosure relates to a carrier storage apparatus, a substrate processing apparatus, and a carrier transfer method.

### BACKGROUND

A substrate processing apparatus including storage shelves that store carriers accommodating a plurality of substrates in multiple stages is disclosed (e.g., see Patent Document 1). In Patent Document 1, each storage shelf is independently movable vertically.

### PRIOR ART DOCUMENT

### Patent Document

Patent Document 1: Japanese Patent No. 6275824

### SUMMARY

Some embodiments of the present disclosure provide a carrier storage apparatus that stores a carrier accommodating a plurality of substrates. The carrier storage apparatus includes: a transfer mechanism configured to transfer the carrier; a first storage shelf group provided closer to a negative side of a first horizontal axis than the transfer mechanism; a second storage shelf group provided closer to a positive side of the first horizontal axis than the transfer mechanism; and a third storage shelf group provided closer to a positive side or a negative side of a second horizontal axis, which is perpendicular to the first horizontal axis, than the transfer mechanism, wherein the first storage shelf group includes a plurality of first storage shelves configured to store the carrier, wherein the second storage shelf group includes a plurality of second storage shelves configured to store the carrier, wherein the third storage shelf group includes a plurality of third storage shelves configured to store the carrier, wherein the plurality of second storage shelves are disposed to be arranged in two or more columns along the second horizontal axis and in two or more stages along a vertical axis, wherein the plurality of third storage shelves are disposed to be arranged in two or more stages along the vertical axis, and each of the plurality of third storage shelves is movable along the vertical axis, and wherein the transfer mechanism is configured to transfer the carrier to the plurality of first storage shelves, the plurality of second storage shelves, and the plurality of third storage shelves.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a side view illustrating a substrate processing apparatus according to a first embodiment.

FIG. 2 is a plan view illustrating the substrate processing apparatus according to the first embodiment.

FIG. 3 is a view illustrating a cross-section taken along line III-III and viewed from a direction of arrows in FIG. 1.

FIG. 4 is a view illustrating a cross-section taken along line IV-IV and viewed from a direction of arrows in FIG. 1.

FIG. 5 is a view illustrating a cross-section taken along line V-V and viewed from a direction of arrows in FIG. 1.

FIG. 6 is a view illustrating an example of a carrier transfer mechanism.

FIGS. 7A and 7B are first views illustrating an example of a third storage shelf.

FIGS. 8A and 8B are second views illustrating the example of the third storage shelf.

FIGS. 9A and 9B are first views illustrating a third storage shelf according to a modification.

FIGS. 10A and 10B are second views illustrating the third storage shelf according to the modification.

FIGS. 11A and 11B are first views illustrating an example of a carrier transfer method according to the first embodiment.

FIGS. 12A and 12B are second views illustrating the example of the carrier transfer method according to the first embodiment.

FIGS. 13A and 13B are third views illustrating the example of the carrier transfer method according to the first embodiment.

FIGS. 14A and 14B are fourth views illustrating the example of the carrier transfer method according to the first embodiment.

FIGS. 15A and 15B are fifth views illustrating the example of the carrier transfer method according to the first embodiment.

FIGS. 16A and 16B are sixth views illustrating the example of the carrier transfer method according to the first embodiment.

FIGS. 17A and 17B are seventh views illustrating the example of the carrier transfer method according to the first embodiment.

FIGS. 18A and 18B are first views illustrating another example of the carrier transfer method according to the first embodiment.

FIGS. 19A and 19B are second views illustrating the another example of the carrier transfer method according to the first embodiment.

FIGS. 20A and 20B are third views illustrating the another example of the carrier transfer method according to the first embodiment.

FIGS. 21A and 21B are fourth views illustrating the another example of the carrier transfer method according to the first embodiment.

FIGS. 22A and 22B are fifth views illustrating the another example of the carrier transfer method according to the first embodiment.

FIGS. 23A and 23B are sixth views illustrating the another example of the carrier transfer method according to the first embodiment.

FIGS. 24A and 24B are seventh views illustrating the another example of the carrier transfer method according to the first embodiment.

FIGS. 25A and 25B are eighth views illustrating the another example of the carrier transfer method according to the first embodiment.

FIG. 26 is a view illustrating a carrier transfer mechanism according to a first modification.

FIG. 27 is a view illustrating a carrier transfer mechanism according to a second modification.

FIG. 28 is a side view illustrating a substrate processing apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments are described with reference to the accompanying drawings. Throughout the drawings, the same or corresponding members or components are denoted by the same or corresponding reference numerals, and duplicated descriptions are omitted.

In this specification, an X axis, a Y axis, and a Z axis are orthogonal to one another. The Y axis is an example of a first horizontal axis, the X axis is an example of a second horizontal axis, and the Z axis is an example of a vertical axis.

### First Embodiment

### (Substrate Processing Apparatus)

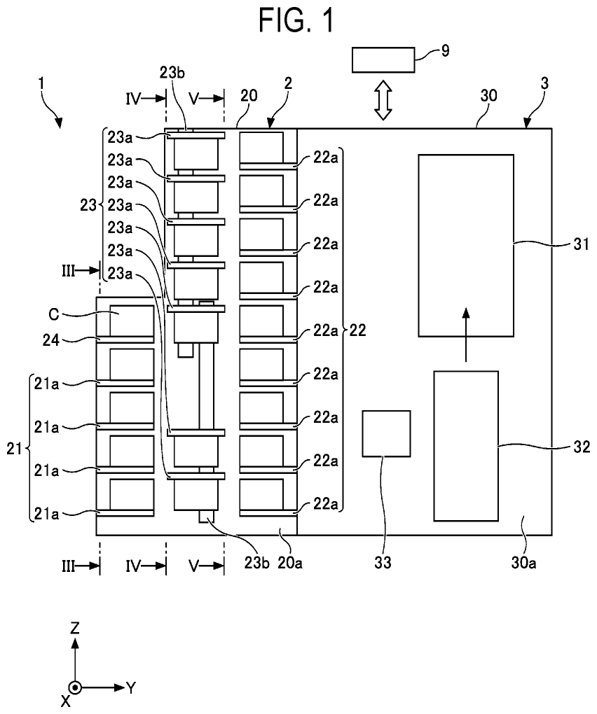

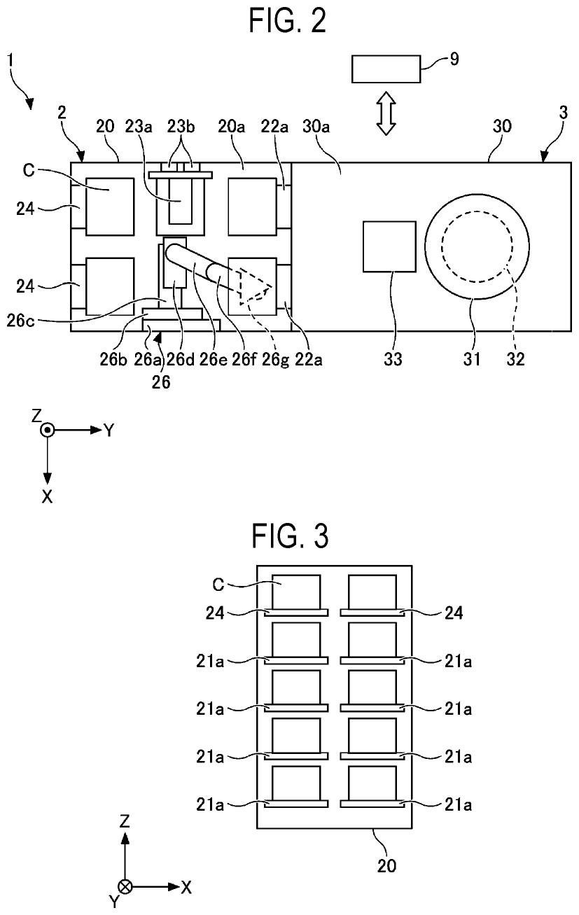

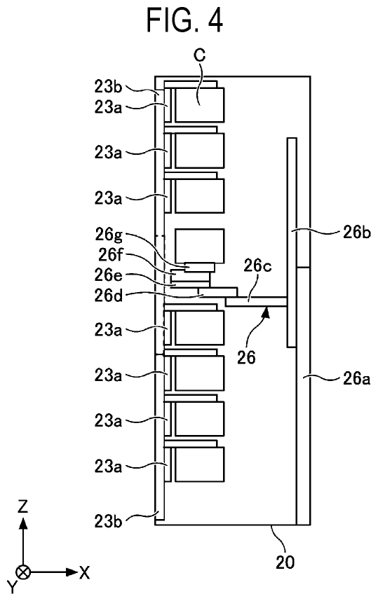

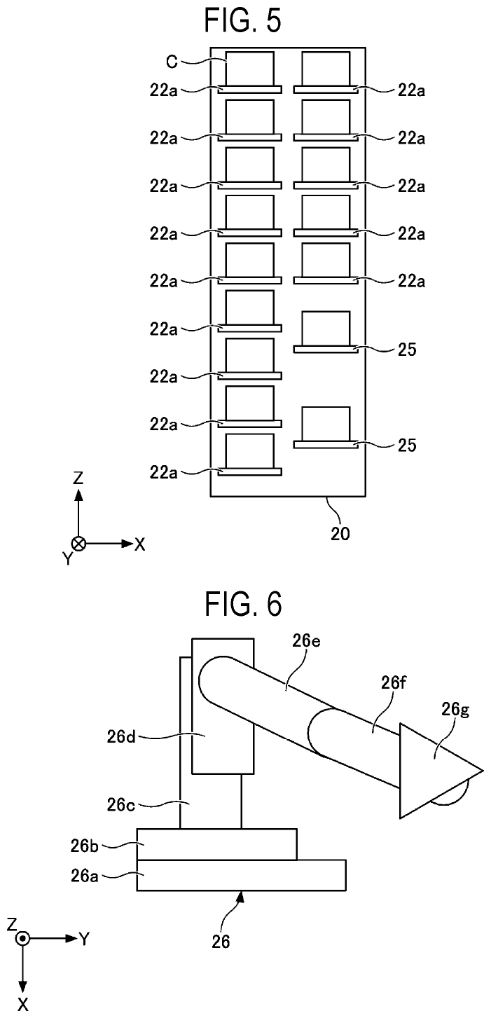

A substrate processing apparatus 1 according to a first embodiment will be described with reference to FIGS. 1 to 5. FIG. 1 is a side view illustrating the substrate processing apparatus 1 according to the first embodiment. FIG. 2 is a plan view illustrating the substrate processing apparatus 1 according to the first embodiment. FIG. 3 is a view illustrating a cross-section taken along line III-III and viewed from a direction of arrows in FIG. 1. FIG. 4 is a view illustrating a cross-section taken along line IV-IV and viewed from a direction of arrows in FIG. 1. FIG. 5 is a view illustrating a cross-section taken along line V-V and viewed from a direction of arrows in FIG. 1.

The substrate processing apparatus 1 includes a loader/unloader 2, a batch processor 3, and a controller 9. The loader/unloader 2 is an example of a carrier storage apparatus.

The loader/unloader 2 includes a housing 20, a first storage shelf group 21, a second storage shelf group 22, a third storage shelf group 23, load ports 24, loaders 25, and a carrier transfer mechanism 26.

The housing 20 forms an internal space 20a. The internal space 20a is maintained, for example, to be an air atmosphere. The first storage shelf group 21, the second storage shelf group 22, the third storage shelf group 23, the load ports 24, the loaders 25, and the carrier transfer mechanism 26 are provided in the internal space 20a.

The first storage shelf group 21 is provided on a Y-axis negative side in the housing 20. The first storage shelf group 21 includes a plurality of first storage shelves 21a. Each first storage shelf 21a temporarily stores a carrier C by holding a bottom plate of the carrier C from below. Each first storage shelf 21a may temporarily store a carrier C by holding a flange provided in a ceiling plate of the carrier C. The carrier C is a container for accommodating and transferring a plurality of (e.g., twenty-five) substrates. The carrier C is, for example, a front opening unified pod (FOUP). In the illustrated example, the first storage shelves 21a are disposed to be arranged in two columns along the X axis and in four stages along the Z axis. The number of the first storage shelves 21a is eight. The number of columns, the number of stages, and the number of the first storage shelves 21a are not limited to those described above.

The second storage shelf group 22 is provided on a Y-axis positive side in the housing 20. The second storage shelf group 22 includes a plurality of second storage shelves 22a.

Each second storage shelf 22a temporarily stores a carrier C by holding a bottom plate of the carrier C from below. Each second storage shelf 22a may temporarily store a carrier C by holding a flange provided in a ceiling plate of the carrier C. In the illustrated example, the second storage shelves 22a are disposed to be arranged in two columns along the X axis. The second storage shelves 22a are disposed to be arranged in nine stages along the Z axis on an X-axis negative side and arranged in five stages along the Z axis on an X-axis positive side. The number of the second storage shelves 22a is fourteen. The number of columns, the number of stages, and the number of the second storage shelves 22a are not limited to those described above.

The third storage shelf group 23 is provided on the X-axis negative side and at a Y-axis center in the housing 20. The third storage shelf group 23 is not provided on the X-axis positive side in the housing 20. The third storage shelf group 23 includes a plurality of third storage shelves 23a. Each third storage shelf 23a temporarily stores a carrier C by holding a flange provided in a ceiling plate of the carrier C. In the illustrated example, the third storage shelves 23a are disposed to be arranged in one column along the X axis and in seven stages along the Z axis. The number of third storage shelves 23a is seven. The number of columns, the number of stages, and the number of the third storage shelves 23a are not limited to those described above. The third storage shelves 23a are movable independently from one another along the Z axis by a lifting mechanism 23b. The lifting mechanism 23b may be divided into a plurality of (e.g., two) lifting mechanisms along the Z axis. The lifting mechanism 23b is, for example, a rack and pinion mechanism.

The load ports 24 are provided on the Y-axis negative side in the housing 20. In the illustrated example, the load ports 24 are disposed to be arranged in two columns along the X axis and in one stage along the Z axis. The number of the load ports 24 is two. The number of columns, the number of stages, and the number of the load ports 24 are not limited to those described above. A carrier C is placed on each load port 24. The carrier C is loaded and unloaded with respect to the load port 24.

The loaders 25 are provided on the Y-axis positive side in the housing 20. The loaders 25 are adjacent to the batch processor 3. In the illustrated example, the loaders 25 are disposed to be arranged in one column along the X axis and in two stages along the Z axis. The number of the loaders 25 is two. The number of columns, the number of stages, and the number of the loaders 25 are not limited to those described above. A carrier C is placed on each loader 25.

Each loader 25 is provided with a lid opening/closing mechanism (not illustrated) for opening and closing a lid of the carrier C.

The carrier transfer mechanism 26 is provided on the X-axis positive side and at the Y-axis center in the housing 20. The carrier transfer mechanism 26 is configured to be capable of transferring a carrier C among the first storage shelf group 21, the second storage shelf group 22, the third storage shelf group 23, the load ports 24, and the loaders 25. The carrier transfer mechanism 26 is configured so that all components constituting the carrier transfer mechanism 26 take postures that do not overlap with carriers C stored on the third storage shelves 23a in a plan view. In this case, in a state in which carriers C are stored on the third storage shelves 23a, the carrier transfer mechanism 26 can move a carrier C along the Z axis while holding the carrier C. Therefore, even when the carriers are stored on the third storage shelves 23a, the carrier transfer mechanism 26 can transfer the carrier C to all storage shelves (the first storage shelves 21a, the second storage shelves 22a, and the third storage shelves 23a). Details of the carrier transfer mechanism 26 will be described later.

The batch processor 3 includes a housing 30, a thermal treatment furnace 31, a boat 32, and a substrate transfer mechanism 33.

The housing 30 is adjacent to the Y-axis positive side of the housing 20. The housing 30 may be attachable and detachable with respect to the housing 20. The housing 30 forms an internal space 30a. The internal space 30a is maintained, for example, to be an inert gas atmosphere. The thermal treatment furnace 31, the boat 32, and the substrate transfer mechanism 33 are provided in the internal space 30a.

The thermal treatment furnace 31 has a substantially cylindrical shape with a ceiling. The thermal treatment furnace 31 accommodates the boat 32. The thermal treatment furnace 31 collectively performs thermal processing for a plurality of substrates held by the boat 32. The thermal processing is, for example, film formation. The thermal processing may be etching.

The boat 32 is provided immediately below the thermal treatment furnace 31. The boat 32 holds a plurality of (e.g., two-hundred or more) substrates in multiple stages. The boat 32 is configured to be movable along the Z axis by a boat elevator (not illustrated). By moving the boat 32 upward along the Z axis, the boat 32 is loaded into the thermal treatment furnace 31.

By moving the boat 32 downward along the Z axis, the boat 32 is unloaded from the thermal treatment furnace 31.

The substrate transfer mechanism 33 transfers the substrate between the carrier C placed on the loader 25 and the boat 32. The substrate transfer mechanism 33 simultaneously transfers, for example, a plurality of (e.g., five) substrates. In this case, it is possible to shorten a time required in transfer of the substrate. However, the substrate transfer mechanism 33 may be configured to transfer the substrates sheet-by-sheet.

The controller 9 is an electronic circuit such as a central processing unit (CPU), a field programmable gate array (FPGA), or an application specific integrated circuit (ASIC). The controller 9 executes instruction codes stored in a memory or is circuit-designed for special use, thereby performing various control operations described in this specification.

### (Carrier Transfer Mechanism)

An example of the carrier transfer mechanism 26 will be described with reference to FIG. 6 in addition to FIGS. 1 to 5. FIG. 6 is a view illustrating an example of the carrier transfer mechanism 26.

The carrier transfer mechanism 26 includes a first guide 26a, a second guide 26b, a first mover 26c, a second mover 26d, a first arm 26e, a second arm 26f, and a hand 26g.

The first guide 26a is fixed to an inner wall of the housing 20 on the X-axis positive side. The first guide 26a extends along the Z axis.

The second guide 26b is connected to the first guide 26a, and is movable along the Z axis while being guided by the first guide 26a. The second guide 26b is driven by power of a motor. The second guide 26b extends along the Z axis.

The first mover 26c is connected to the second guide 26b, and is movable along the Z axis while being guided by the second guide 26b. The first mover 26c is driven by power of a motor. The first mover 26c extends along the X axis.

The second mover 26d is connected to the first mover 26c, and is movable along the X axis while being guided by the first mover 26c. The second mover 26d is driven by power of a motor. The second mover 26d extends along the X axis.

The first arm 26e is connected to the second mover 26d, and is rotatable horizontally. The first arm 26e is driven by power of a motor.

The second arm 26f is connected to the first arm 26e, and is rotatable horizontally. The second arm 26f is driven interlocking with an operation of the first arm 26e.

The hand 26g is connected to a tip end of the second arm 26f, and is rotatable horizontally. The hand 26g is driven by power of a motor.

The carrier transfer mechanism 26 is configured so that the first guide 26a, the second guide 26b, the first mover 26c, the second mover 26d, the first arm 26e, the second arm 26f, and the hand 26g take postures that do not overlap with carriers C stored on the third storage shelves 23a in a plan view. In this case, in a state in which the carriers C is stored on the third storage shelves 23a, the carrier transfer mechanism 26 can move a carrier C along the Z axis while holding the carrier C. Therefore, even when the carriers are stored on the third storage shelves 23a, the carrier transfer mechanism 26 can transfer the carrier C to all the storage shelves (the first storage shelves 21a, the second storage shelves 22a, and the third storage shelves 23a).

The motors used in the carrier transfer mechanism 26 is, for example, a stepping motor.

The first guide 26a, the second guide 26b, and the first mover 26c are an example of a lifting mechanism. The first mover 26c and the second mover 26d are an example of a first arm that extends and contracts along the X axis. The first arm 26e and the second arm 26f are an example of a second arm that extends and contracts along the Y axis.

### (Third Storage Shelf)

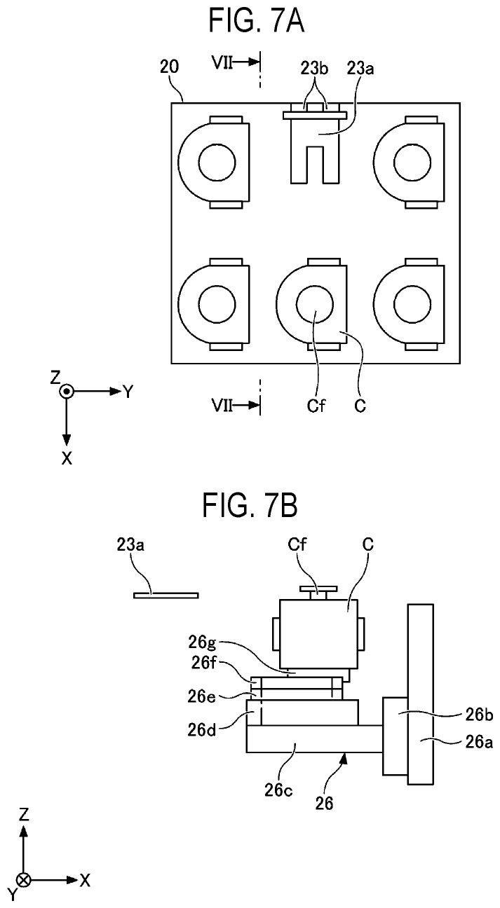

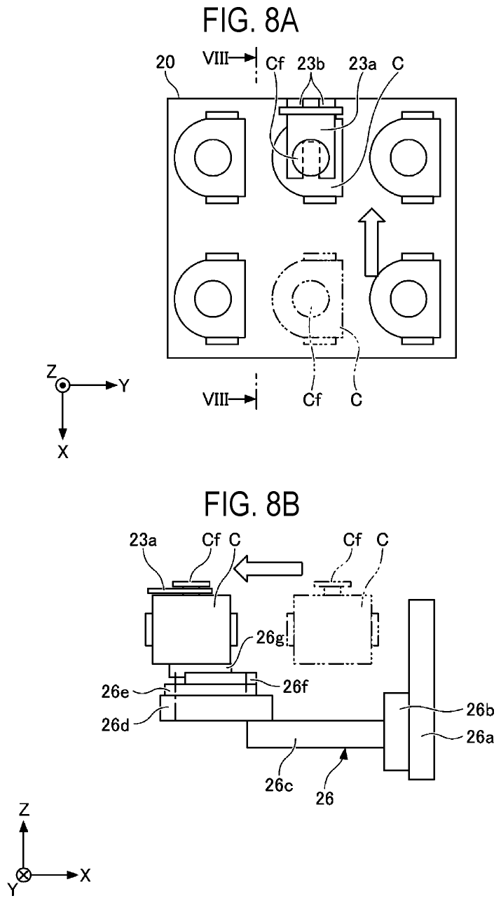

The third storage shelf 23a will be described with reference to FIGS. 7A to 8B. FIGS. 7A to 8B are views illustrating an example of the third storage shelf 23a. FIGS. 7A and 7B are views illustrating a state in which the third storage shelf 23a does not hold a carrier C. FIG. 7A is a plan view, and FIG. 7B is a view illustrating a cross-section taken along line VII-VII and viewed from a direction of arrows in FIG. 7A. FIGS. 8A and 8B are views illustrating a state in which the third storage shelf 23a holds a carrier C. In FIGS. 8A and 8B, the carrier C before being held by the third storage shelf 23a is indicated by an alternate long and two short dashes line, and a direction in which the third storage shelf 23a moves is indicated by an arrow. FIG. 8A is a plan view, and FIG. 8B is a view illustrating a cross-section taken along line VIII-VIII and viewed from a direction of arrows in FIG. 8A.

The third storage shelf 23a has a plate shape. The third storage shelf 23a has a substantially U shape which is open toward the X-axis positive side in a plan view, and temporarily stores the carrier C by holding a flange Cf provided in a ceiling plate of the carrier C.

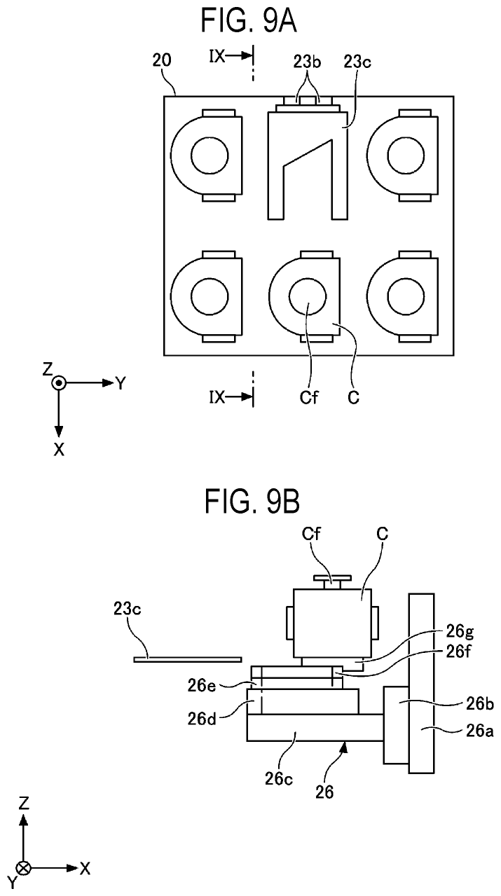

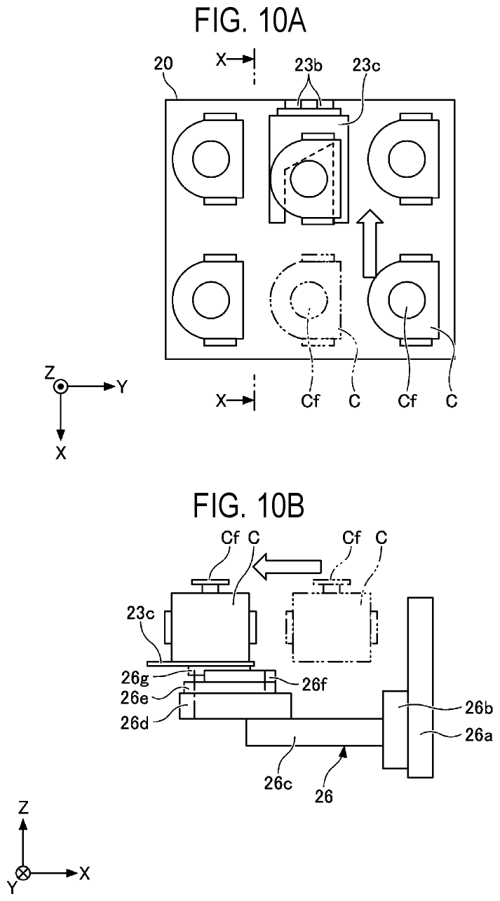

A third storage shelf 23c according to a modification will be described with reference to FIGS. 9A to 10B. FIGS. 9A to 10B are views illustrating the third storage shelf 23c according to the modification. FIGS. 9A and 9B are views illustrating a state in which the third storage shelf 23c does not hold a carrier C. FIG. 9A is a plan view, and FIG. 9B is a view illustrating a cross-section taken along line IX-IX and viewed from a direction of arrows in FIG. 9A. FIGS. 10A and 10B are views illustrating a state in which the third storage shelf 23c holds a carrier C. In FIGS. 10A and 10B, the carrier C before being held by the third storage shelf 23c is indicated by an alternate long and two short dashes line, and a direction in which the third storage shelf 23c moves is indicated by an arrow. FIG. 10A is a plan view, and FIG. 10B is a view illustrating a cross-section taken along line X-X and viewed from a direction of arrows in FIG. 10A.

The third storage shelf 23c has a plate shape. The third storage shelf 23c has a substantially U shape which is open toward the X-axis positive side in a plan view, and temporarily stores the carrier C by holding a bottom plate of the carrier C from below.

### (Carrier Transfer Method)

A carrier transfer method of transferring the carrier C in the substrate processing apparatus 1 will be described. The carrier transfer method described below is performed under control of the controller 9.

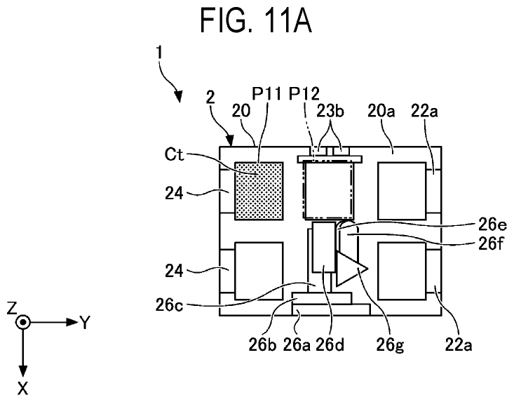

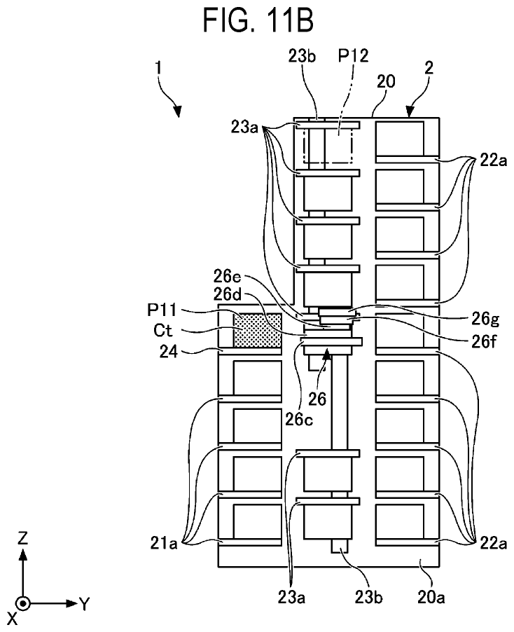

Referring to FIGS. 11A to 17B, a method of transferring the carrier C from the load port 24 provided on the X-axis negative side in the housing 20 to the third storage shelf 23a provided at an uppermost stage in the housing 20 will be described.

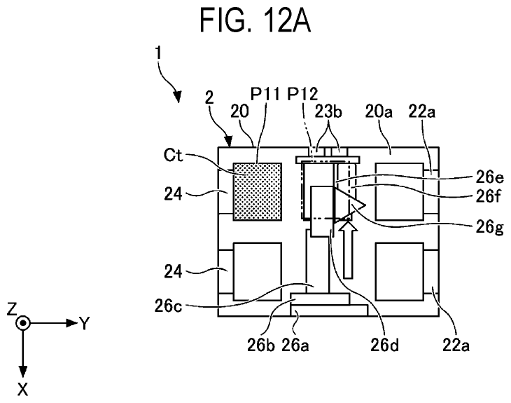

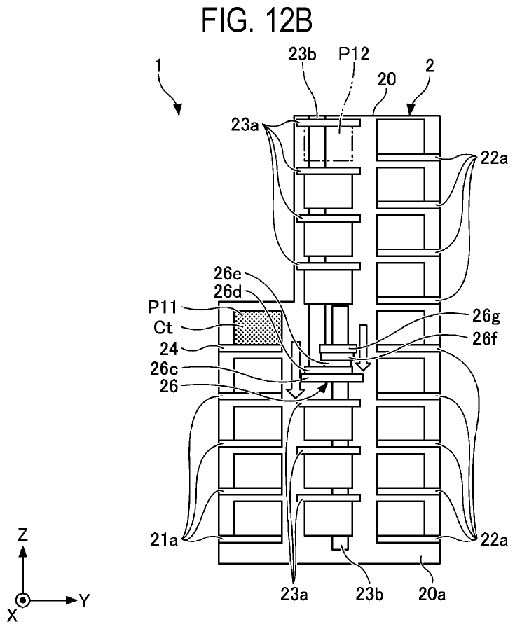

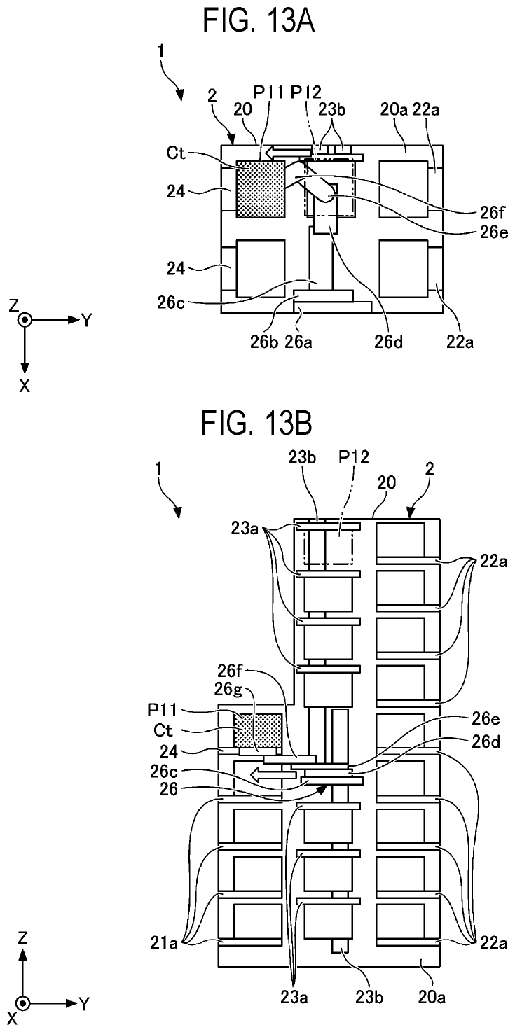

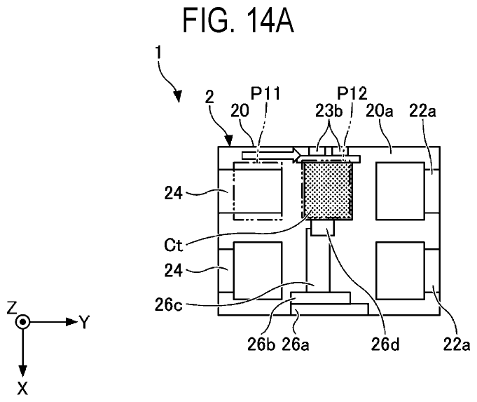

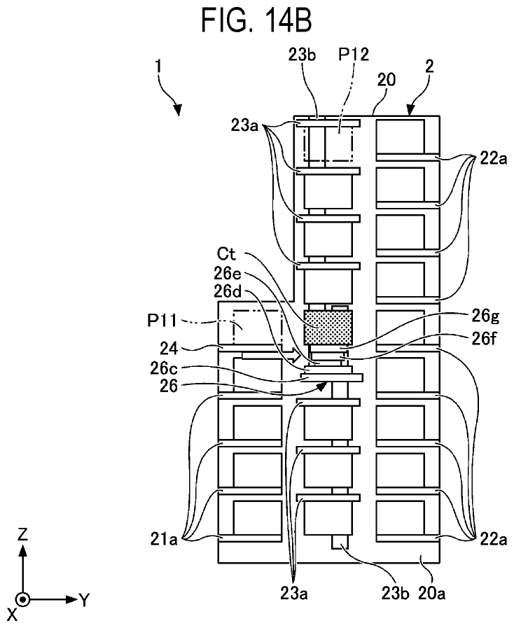

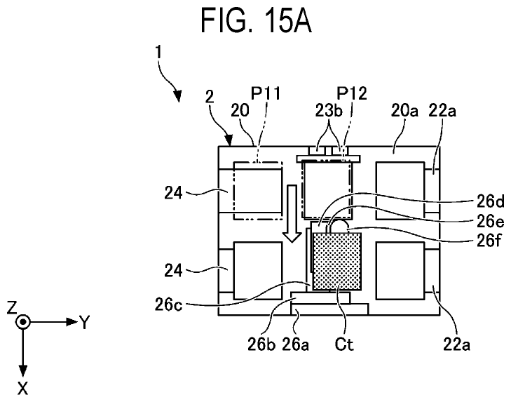

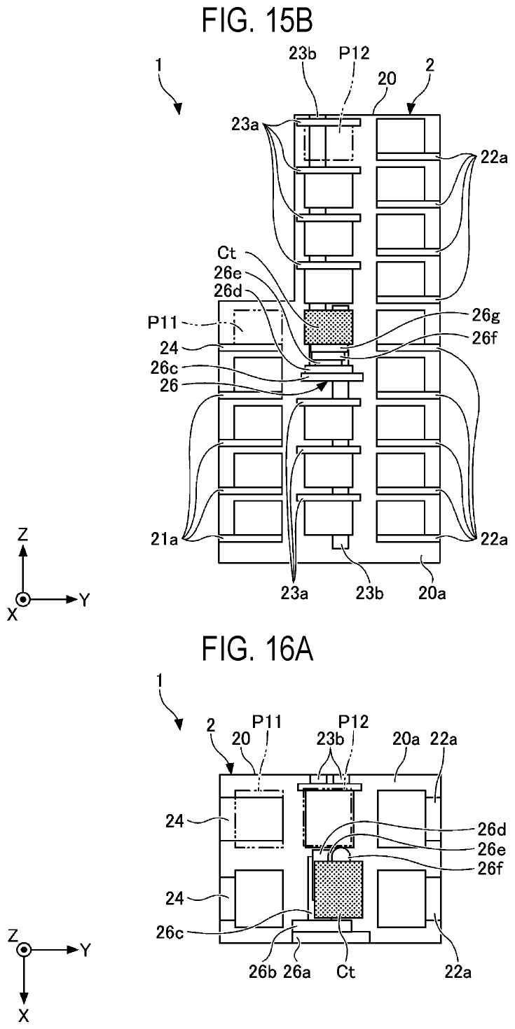

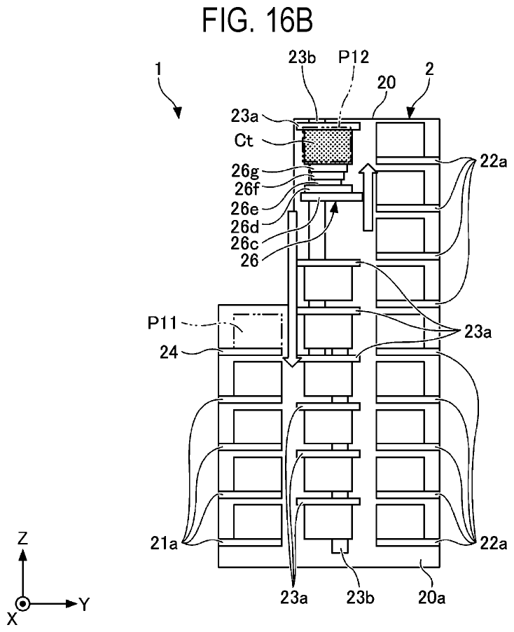

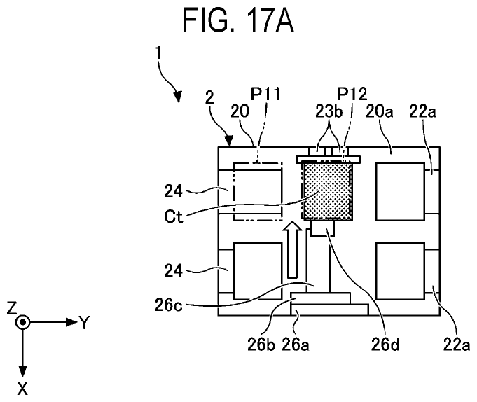

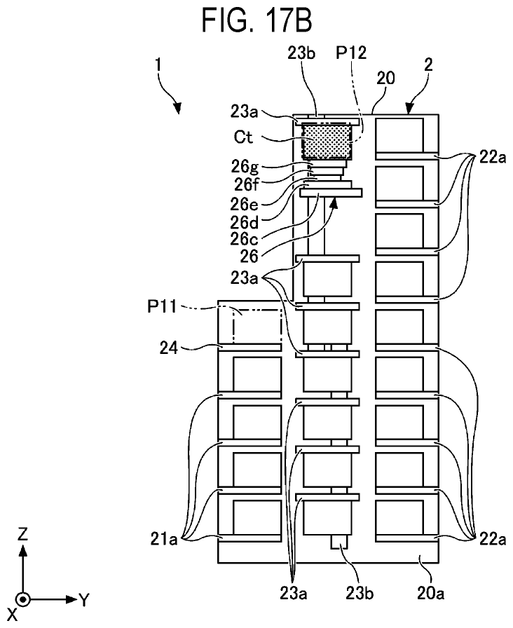

FIGS. 11A to 17B are views illustrating an example of a carrier transfer method according to the first embodiment. FIG. 11A, FIG. 12A, FIG. 13A, FIG. 14A, FIG. 15A, FIG. 16A, and FIG. 17A are plan views. FIG. 11B, FIG. 12B, FIG. 13B, FIG. 14B, FIG. 15B, FIG. 16B, and FIG. 17B are side views. In FIGS. 11A to 17B, a position of a transfer source is indicated by P11, a position of a transfer destination is indicated by P12, and the carrier C as a transfer target is indicated by Ct.

First, as illustrated in FIGS. 11A and 11B, a transfer device (not illustrated) provided outside the substrate processing apparatus 1 loads the carrier Ct as a transfer target into the load port 24 provided on the X-axis negative side in the housing 20. The transfer device is, for example, an overhead hoist transport (OHT). An operator may load the carrier Ct as a transfer target into the load port 24 provided on the X-axis negative side in the housing 20.

Subsequently, as illustrated in FIGS. 12A and 12B, the third storage shelf 23a located at the same height as the load port 24 is moved down. When the third storage shelf 23a located at the same height as the load port 24 does not exist, the operation of moving down the third storage shelf 23a may be omitted. Subsequently, the carrier transfer mechanism 26 causes the second guide 26b and the first mover 26c to move the hand 26g down to a receiving height for the carrier Ct. Subsequently, the carrier transfer mechanism 26 causes the second mover 26d to move the hand 26g horizontally toward the X-axis negative side.

Subsequently, as illustrated in FIGS. 13A and 13B, the carrier transfer mechanism 26 causes the first arm 26e and the second arm 26f to move the hand 26g horizontally toward the Y-axis negative side to a location below the carrier Ct, thereby holding the carrier Ct by the hand 26g.

Subsequently, as illustrated in FIGS. 14A and 14B, the carrier transfer mechanism 26 causes the first arm 26e and the second arm 26f to move the hand 26g holding the carrier Ct horizontally toward the Y-axis positive side.

Subsequently, as illustrated in FIGS. 15A and 15B, the carrier transfer mechanism 26 causes the second mover 26d to move the hand 26g holding the carrier Ct horizontally toward the X-axis positive side.

Subsequently, as illustrated in FIGS. 16A and 16B, the third storage shelves 23a in a second stage, a third stage, and a fourth stage from the uppermost stage are moved down. Subsequently, the carrier transfer mechanism 26 causes the second guide 26b and the first mover 26c to move the hand 26g holding the carrier Ct up to a height position at which the carrier Ct is delivered to the third storage shelf 23a as the transfer destination.

Subsequently, as illustrated in FIGS. 17A and 17B, the carrier transfer mechanism 26 causes the second mover 26d to move the hand 26g holding the carrier Ct horizontally toward the X-axis negative side, thereby holding the carrier Ct on the third storage shelf 23a as the transfer destination. Subsequently, the carrier transfer mechanism 26 causes the second mover 26d to move the hand 26g horizontally toward the X-axis positive side.

As described above, it is possible to transfer the carrier Ct from the load port 24 provided on the X-axis negative side in the housing 20 to the third storage shelf 23a provided in the uppermost stage in the housing 20. Further, when transferring the carrier Ct from the third storage shelf 23a provided in the uppermost stage in the housing 20 to the load port 24 provided on the X-axis negative side in the housing 20, it is possible to transfer carrier Ct by performing operations sequentially in a reverse manner to those shown in FIGS. 11A to 17B.

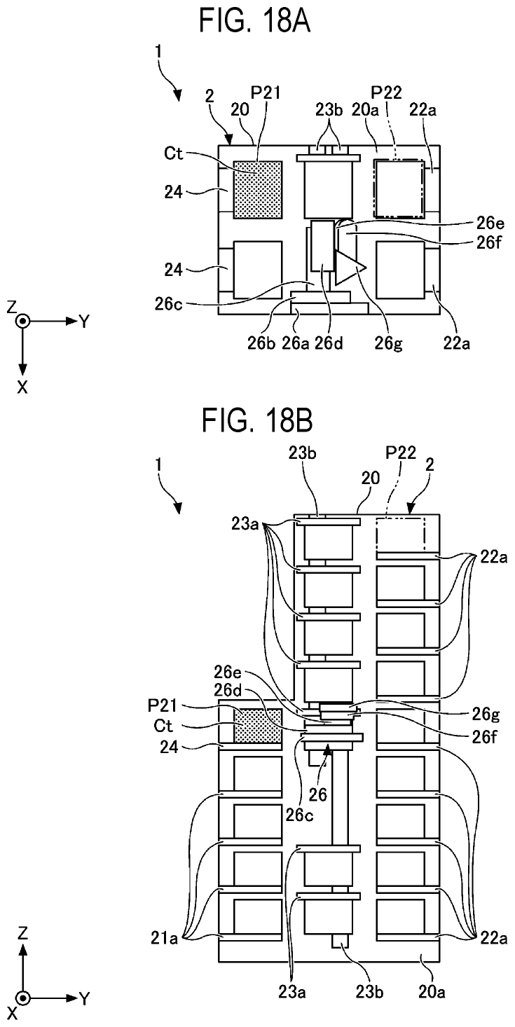

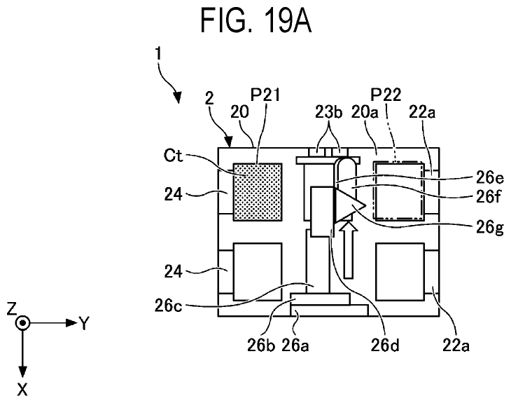

Referring to FIGS. 18A to 25B, a method of transferring a carrier C from the load port 24 provided on the X-axis negative side in the housing 20 to the second storage shelf 22a provided at an uppermost stage on the X-axis negative side in the housing 20 will be described.

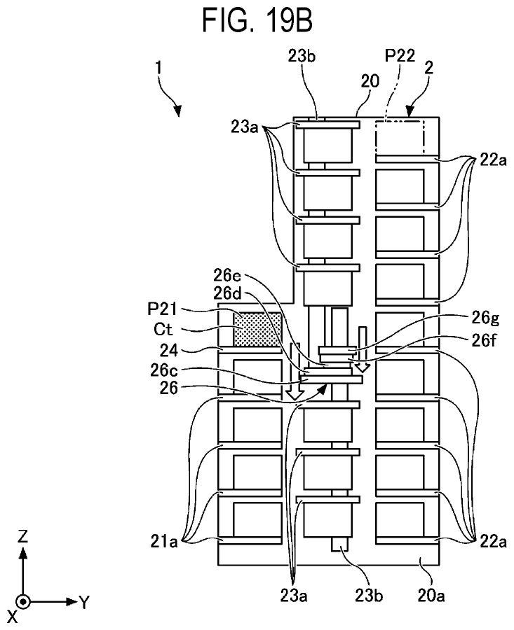

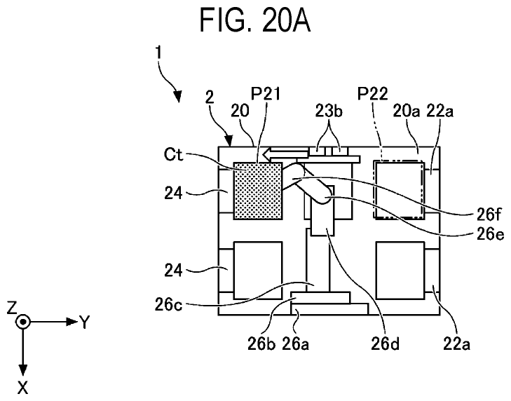

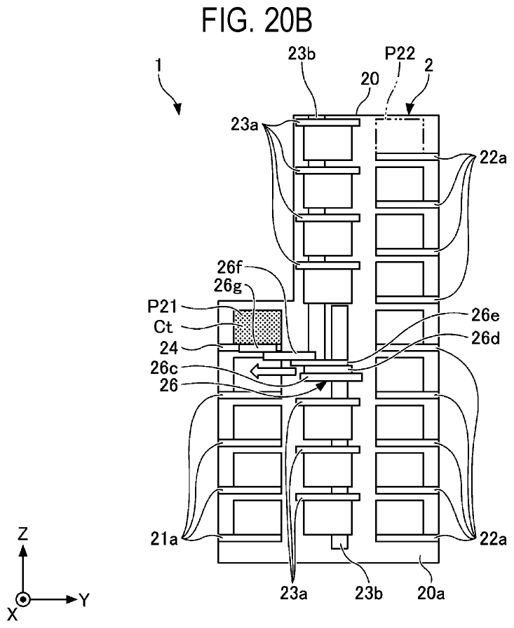

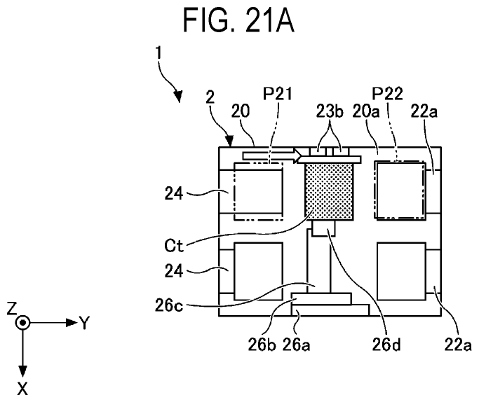

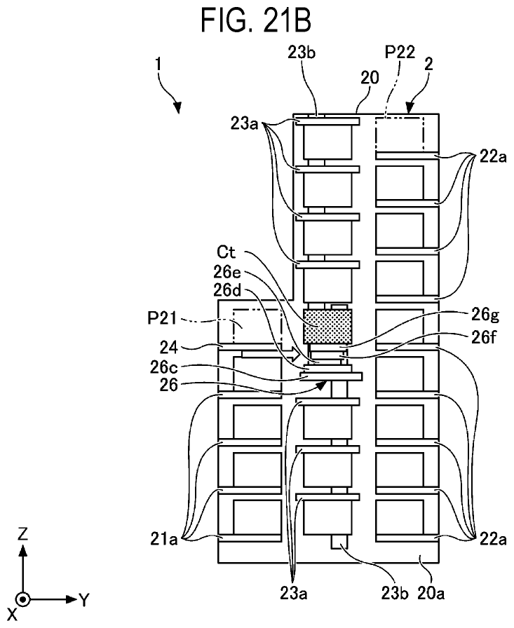

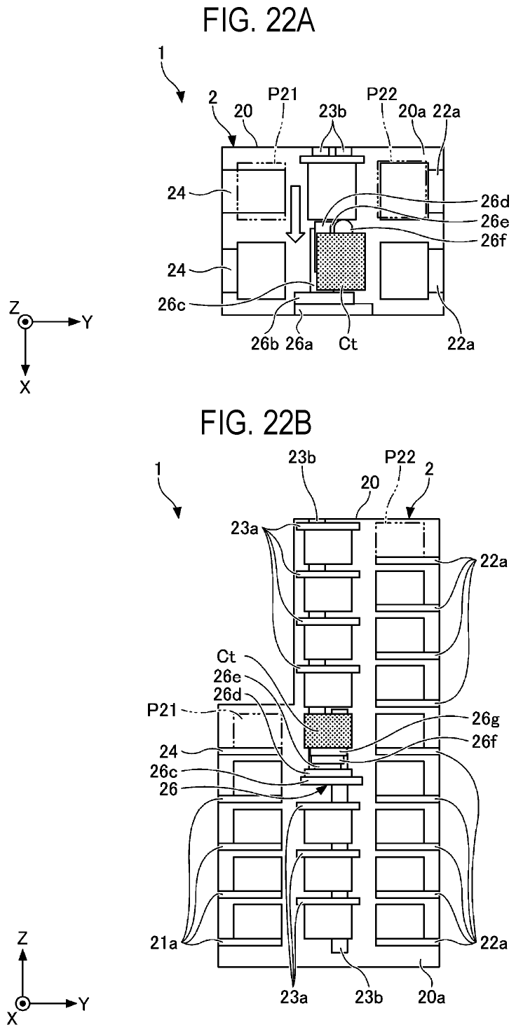

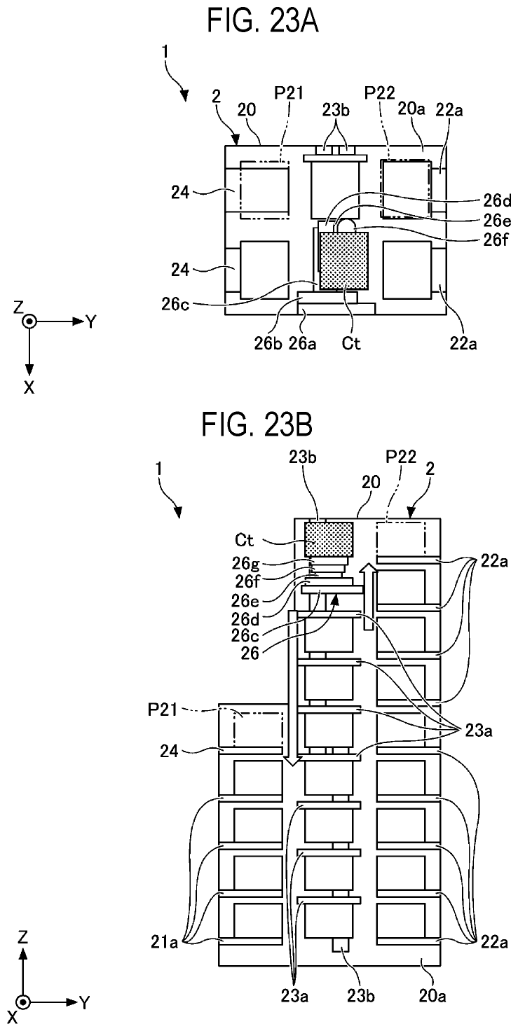

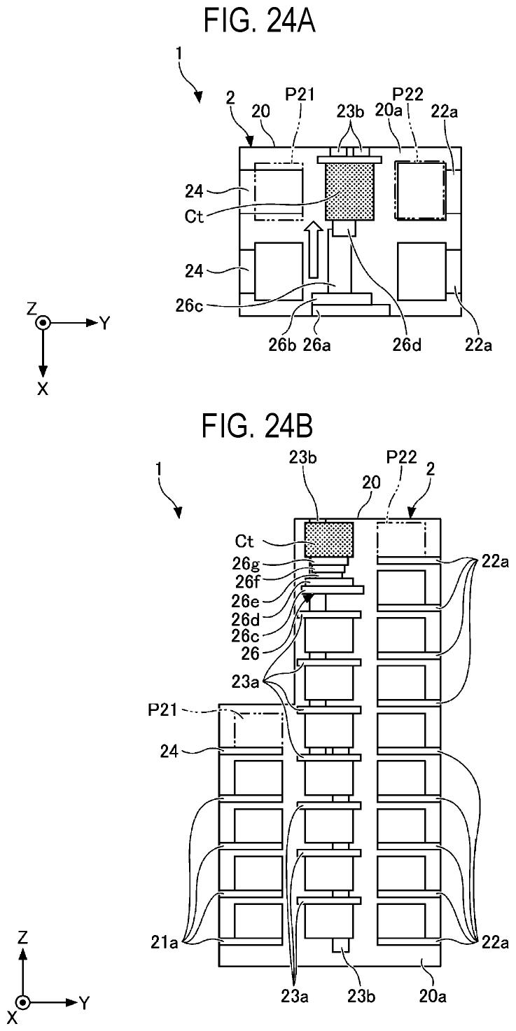

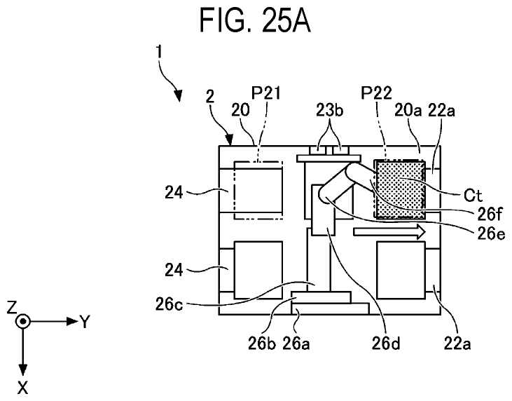

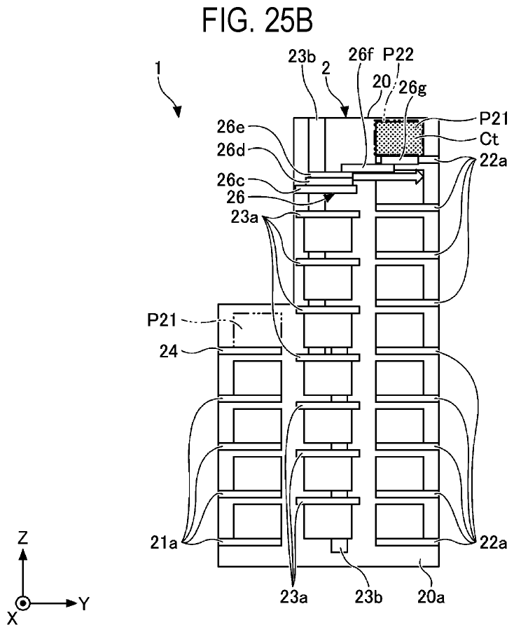

FIGS. 18A to 25B are views illustrating another example of the carrier transfer method according to the first embodiment. FIG. 18A, FIG. 19A, FIG. 20A, FIG. 21A, FIG. 22A, FIG. 23A, FIG. 24A, and FIG. 25A are plan views. FIG. 18B, FIG. 19B, FIG. 20B, FIG. 21B, FIG. 22B, FIG. 23B, FIG. 24B, and FIG. 25B are side views. In FIGS. 18A to 25B, a position of a transfer source is indicated by P21, a position of a transfer destination is indicated by P22, and the carrier C to be transferred is indicated by Ct.

First, as illustrated in FIGS. 18A and 18B, a transfer device (not illustrated) provided outside the substrate processing apparatus 1 loads the carrier Ct as a transfer target into the load port 24 provided on the X-axis negative side in the housing 20. The operator may load the carrier Ct as a transfer target into the load port 24 provided on the X-axis negative side in the housing 20.

Subsequently, as illustrated in FIGS. 19A and 19B, the third storage shelf 23a located at the same height as the load port 24 is moved down. When the third storage shelf 23a located at the same height as the load port 24 does not exist, the operation of moving down the third storage shelf 23a may be omitted. Subsequently, the carrier transfer mechanism 26 causes the second guide 26b and the first mover 26c to move the hand 26g down to a receiving height for the carrier Ct. Subsequently, the carrier transfer mechanism 26 causes the second mover 26d to move the hand 26g horizontally toward the X-axis negative side.

Subsequently, as illustrated in FIGS. 20A and 20B, the carrier transfer mechanism 26 causes the first arm 26e and the second arm 26f to move the hand 26g horizontally toward the Y-axis negative side to a location below the carrier Ct, thereby holding the carrier Ct by the hand 26g.

Subsequently, as illustrated in FIGS. 21A and 21B, the carrier transfer mechanism 26 causes the first arm 26e and the second arm 26f to move the hand 26g holding the carrier Ct horizontally toward the Y-axis positive side.

Subsequently, as illustrated in FIGS. 22A and 22B, the carrier transfer mechanism 26 causes the second mover 26d to move the hand 26g holding the carrier Ct horizontally toward the X-axis positive side.

Subsequently, as illustrated in FIGS. 23A and 23B, the third storage shelves 23a in a first stage, a second stage, a third stage, and a fourth stage from the uppermost stage are moved down. Subsequently, the carrier transfer mechanism 26 causes the second guide 26b and the first mover 26c to move the hand 26g holding the carrier Ct up to a height position at which the carrier Ct is delivered to the second storage shelf 22a as the transfer destination.

Subsequently, as illustrated in FIGS. 24A and 24B, the carrier transfer mechanism 26 causes the second mover 26d to move the hand 26g holding the carrier Ct horizontally toward the X-axis negative side.

Subsequently, as illustrated in FIGS. 25A and 25B, the carrier transfer mechanism 26 causes the first arm 26e and the second arm 26f to move the hand 26g holding the carrier Ct horizontally toward the Y-axis positive side, thereby holding the carrier Ct on the second storage shelf 22a as the transfer destination. Subsequently, the carrier transfer mechanism 26 causes the first arm 26e and the second arm 26f to move the hand 26g horizontally toward the Y-axis negative side. Subsequently, the carrier transfer mechanism 26 causes the second mover 26d to move the hand 26g horizontally toward the X-axis positive side.

As described above, it is possible to transfer the carrier Ct from the load port 24 provided on the X-axis negative side in the housing 20 to the second storage shelf 22a provided in the uppermost stage on the X-axis negative side in the housing 20. Further, when transferring the carrier Ct from the second storage shelf 22a provided in the uppermost stage on the X-axis negative side in the housing 20 to the load port 24 provided on the X-axis negative side in the housing 20, it is possible to transfer carrier Ct by performing operations sequentially in a reverse manner to those shown in FIGS. 18A to 25B.

In addition, the position of the transfer source and the position of the transfer destination are not limited to the above-described example.

### (Carrier Transfer Mechanism According to First Modification)

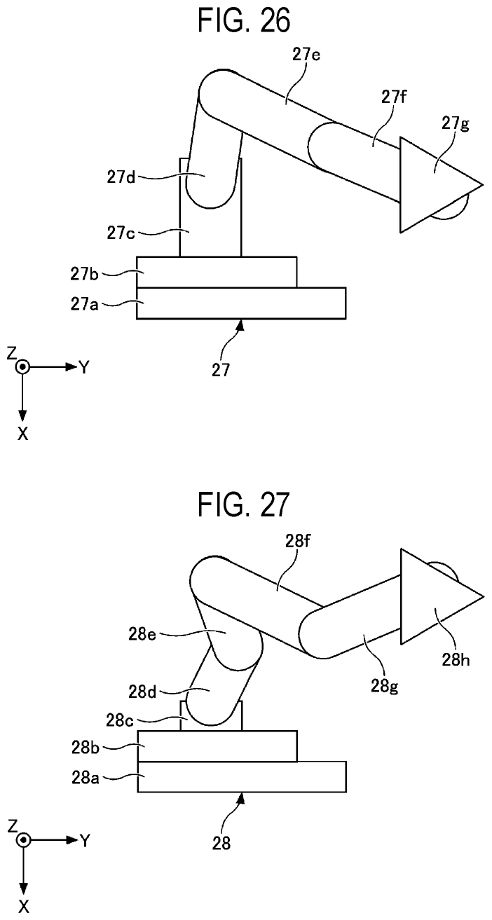

A carrier transfer mechanism 27 according to a first modification will be described with reference to FIG. 26. FIG. 26 is a view illustrating the carrier transfer mechanism 27 according to the first modification. As illustrated in FIG. 26, the carrier transfer mechanism 27 is different from the carrier transfer mechanism 26 in a configuration including a first arm 27d instead of the second mover 26d.

The carrier transfer mechanism 27 includes a first guide 27a, a second guide 27b, a first mover 27c, the first arm 27d, a second arm 27e, a third arm 27f, and a hand 27g.

The first guide 27a is fixed to the inner wall on the X-axis positive side in the housing 20. The first guide 27a extends along the Z axis.

The second guide 27b is connected to the first guide 27a, and is movable along the Z axis while being guided by the first guide 27a. The second guide 27b is driven by power of a motor. The second guide 27b extends along the Z axis.

The first mover 27c is connected to the second guide 27b, and is movable along the Z axis while being guided by the second guide 27b. The first mover 27c is driven by power of a motor. The first mover 27c extends along the X axis.

The first arm 27d is connected to the first mover 27c, and is rotatable horizontally. The first arm 27d is driven by power of a motor.

The second arm 27e is connected to the first arm 27d, is rotatable horizontally. The second arm 27e is driven by power of a motor. The second arm 27e is driven independently from the first arm 27d.

The third arm 27f is connected to the second arm 27e, and is rotatable horizontally. The third arm 27f is driven by power of a motor. The third arm 27f is driven independently from the second arm 27e.

The hand 27g is connected to a tip end of the third arm 27f, and is rotatable horizontally. The hand 27g is driven by power of a motor.

The carrier transfer mechanism 27 is configured so that the first guide 27a, the second guide 27b, the first mover 27c, the first arm 27d, the second arm 27e, the third arm 27f, and the hand 27g take postures that do not overlap with carriers C stored on the third storage shelves 23a in a plan view. In this case, in a state in which carriers C are stored on the third storage shelves 23a, the carrier transfer mechanism 27 can move a carrier C along the Z axis while holding the carrier C. Therefore, even when the carriers are stored on the third storage shelves 23a, the carrier transfer mechanism 27 can transfer the carrier C to all the storage shelves (the first storage shelves 21a, the second storage shelves 22a, and the third storage shelves 23a).

The motors used in the carrier transfer mechanism 27 are a direct drive motor, a servo motor, or the like.

The first arm 27d, the second arm 27e, the third arm 27f, and the hand 27g are horizontally rotated independently from one another by power of the motors. The first guide 27a, the second guide 27b, and the first mover 27c are an example of a lifting mechanism. The first arm 27d, the second arm 27e, and the third arm 27f are an example of an arm that extends and contracts along the X axis and the Y axis. The carrier transfer mechanism 27 may include four or more arms.

### (Carrier Transfer Mechanism According to Second Modification)

A carrier transfer mechanism 28 according to a second modification will be described with reference to FIG. 27. FIG. 27 is a view illustrating the carrier transfer mechanism 28 according to the second modification. As illustrated in FIG. 27, the carrier transfer mechanism 28 is different from the carrier transfer mechanism 26 in a configuration including a first arm 28d and a second arm 28e instead of the second mover 26d.

The carrier transfer mechanism 28 includes a first guide 28a, a second guide 28b, a first mover 28c, the first arm 28d, the second arm 28e, a third arm 28f, a fourth arm 28g, and a hand 28h.

The first guide 28a is fixed to the inner wall on the X-axis positive side in the housing 20. The first guide 28a extends along the Z axis.

The second guide 28b is connected to the first guide 28a, and is movable along the Z axis while being guided by the first guide 28a. The second guide 28b is driven by power of a motor. The second guide 28b extends along the Z axis.

The first mover 28c is connected to the second guide 28b, and is movable along the Z axis while being guided by the second guide 28b. The first mover 28c is driven by power of a motor. The first mover 28c extends along the X axis.

The first arm 28d is connected to the first mover 28c, and is rotatable horizontally. The first arm 28d is driven by power of a motor.

The second arm 28e is connected to the first arm 28d, and is rotatable horizontally. The second arm 28e is driven interlocking with an operation of the first arm 28d.

The third arm 28f is connected to the second arm 28e, and is rotatable horizontally. The third arm 28f is driven by power of a motor.

The fourth arm 28g is connected to the third arm 28f, and is rotatable horizontally. The fourth arm 28g is driven interlocking with an operation of the third arm 28f.

The hand 28h is connected to a tip end of the fourth arm 28g, and is rotatable horizontally. The hand 28h is driven by power of a motor.

The carrier transfer mechanism 28 is configured so that the first guide 28a, the second guide 28b, the first mover 28c, the first arm 28d, the second arm 28e, the third arm 28f, the fourth arm 28g, and the hand 28h take postures that do not overlap with carriers C stored on the third storage shelves 23a in a plan view. In this case, in a state in which carriers C are stored on the third storage shelves 23a, the carrier transfer mechanism 28 can move a carrier C along the Z axis while holding the carrier C. Therefore, even when the carriers are stored on the third storage shelves 23a, the carrier transfer mechanism 28 can transfer the carrier C to all the storage shelves (the first storage shelves 21a, the second storage shelves 22a, and the third storage shelves 23a).

The motors used in the carrier transfer mechanism 28 are, for example, a stepping motor.

The first guide 28a, the second guide 28b, and the first mover 28c are an example of a lifting mechanism. The first arm 28d and the second arm 28e are an example of a first arm that extends and contracts along the X axis. The third arm 28f and the fourth arm 28g are an example of a second arm that extends and contracts along the Y axis.

Conventionally, no storage shelf was provided in a region of Y-axis center in the housing 20, because any storage shelves provided therein may interrupt operations of the carrier transfer mechanism. Therefore, when there is a limitation in a width or a height of an apparatus, it was difficult to increase the number of storage shelves, and hence it was difficult to increase the number of carriers C that can be stored.

In contrast, according to the embodiment, the first storage shelf group 21 is provided on the Y-axis negative side of the carrier transfer mechanism 26, the second storage shelf group 22 is provided on the Y-axis positive side of the carrier transfer mechanism 26, and the third storage shelf group 23 is provided on the X-axis negative side of the carrier transfer mechanism 26. The carrier transfer mechanism 26 is configured to be capable of transferring the carrier C to the plurality of first storage shelves 21a of the first storage shelf group 21, the plurality of second storage shelves 22a of the second storage shelf group 22, and the plurality of third storage shelves 23a of the third storage shelf group 23. In this case, since storage shelves exist in the region of the Y-axis center in the housing 20, it is possible to increase the number of carriers C that can be stored. Further, the third storage shelves 23a of the third storage shelf group 23 are movable along the Z axis. In this case, it is possible to form a transfer space when the carrier transfer mechanism 26 transfers the carrier C to the X-axis negative side in the housing 20.

### Second Embodiment

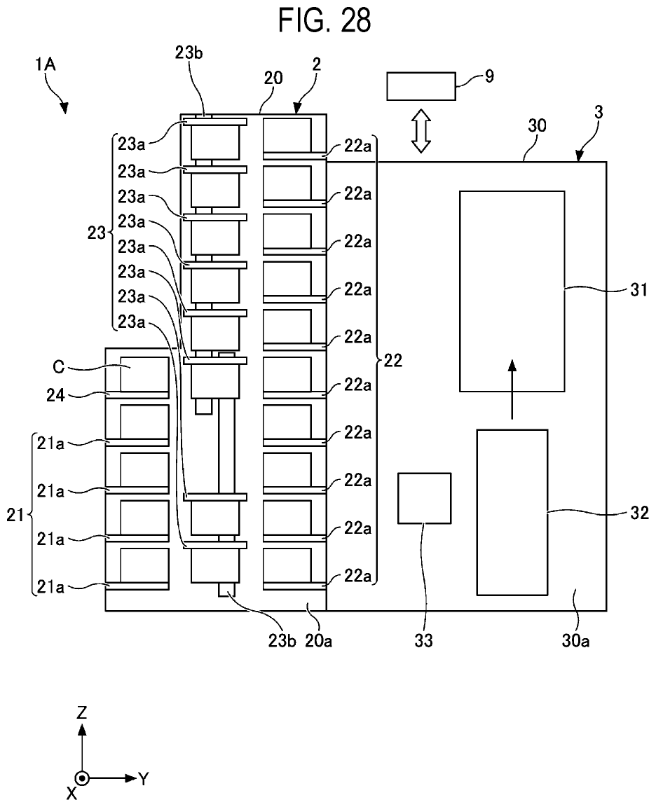

A substrate processing apparatus 1A according to a second embodiment will be described with reference to FIG. 28. FIG. 28 is a side view illustrating the substrate processing apparatus 1A according to the second embodiment.

As illustrated in FIG. 28, the substrate processing apparatus 1A is different from the substrate processing apparatus 1 in a configuration in which a height of a ceiling plate of the housing 20 of the loader/unloader 2 is higher than a height of a ceiling plate of the housing 30 of the batch processor 3, and in which one stage of the second storage shelves 22a and one stage of the third storage shelf 23a are added as uppermost stages. The substrate processing apparatus 1A includes eight first storage shelves 21a, sixteen second storage shelves 22a, and eight third storage shelves 23a. That is, the substrate processing apparatus 1A includes thirty-two storage shelves. Other configurations are the same as those of the substrate processing apparatus 1. According to the substrate processing apparatus 1A, it is possible to increase the number of storage shelves by three as compared with the substrate processing apparatus 1. Thus, it is possible to further increase the number of carriers C that can be stored.

When there is no limitation in a height at which the load ports 24 are provided, it is possible to provide the load ports 24 at a higher position, and to add one stage or two or more stages of the first storage shelves 21a at locations below the load ports 24. In this case, it is possible to increase the number of storage shelves by two or four or more, as compared with the substrate processing apparatus 1. Thus, it is possible to further increase the number of carriers C that can be stored.

According to the present disclosure in some embodiments, it is possible to increase the number of carriers that can be stored.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A carrier storage apparatus that stores a carrier accommodating a plurality of substrates, comprising:
a transfer mechanism configured to transfer the carrier;
a first storage shelf group provided closer to a negative side of a first horizontal axis than the transfer mechanism;
a second storage shelf group provided closer to a positive side of the first horizontal axis than the transfer mechanism; and
a third storage shelf group provided closer to a positive side or a negative side of a second horizontal axis, which is perpendicular to the first horizontal axis, than the transfer mechanism,
wherein the first storage shelf group includes a plurality of first storage shelves configured to store the carrier,
wherein the second storage shelf group includes a plurality of second storage shelves configured to store the carrier,
wherein the third storage shelf group includes a plurality of third storage shelves configured to store the carrier,
wherein the plurality of second storage shelves are disposed to be arranged in two or more columns along the second horizontal axis and in two or more stages along a vertical axis,
wherein the plurality of third storage shelves are disposed to be arranged in two or more stages along the vertical axis, and each of the plurality of third storage shelves is movable along the vertical axis, and
wherein the transfer mechanism is configured to transfer the carrier to the plurality of first storage shelves, the plurality of second storage shelves, and the plurality of third storage shelves.

2. The carrier storage apparatus of claim 1, wherein the transfer mechanism includes:
an arm configured to extend and contract along the first horizontal axis and the second horizontal axis;
a hand connected to a tip end of the arm and configured to hold the carrier; and
a lifting mechanism connected to a base end of the arm and configured to move the arm along the vertical axis.

3. The carrier storage apparatus of claim 2, wherein each of the plurality of third storage shelves holds a bottom plate of the carrier from below.

4. The carrier storage apparatus of claim 1, wherein the transfer mechanism includes:
a first arm configured to extend and contract along the second horizontal axis;
a second arm connected to a tip end of the first arm and configured to extend and contract along the first horizontal axis;
a hand connected to a tip end of the second arm and configured to hold the carrier; and
a lifting mechanism connected to a base end of the first arm and configured to move the first arm along the vertical axis.

5. The carrier storage apparatus of claim 1, wherein each of the plurality of third storage shelves holds a bottom plate of the carrier from below.

6. The carrier storage apparatus of claim 1, wherein each of the plurality of third storage shelves holds a flange provided in a ceiling plate of the carrier.

7. A substrate processing apparatus, comprising:
a carrier storage apparatus configured to store a carrier accommodating a plurality of substrates; and
a batch processor provided closer to a positive side of a first horizontal axis than the carrier storage apparatus, and configured to collectively perform processing for the plurality of substrates,
wherein the carrier storage apparatus comprises:
a transfer mechanism configured to transfer the carrier;
a first storage shelf group provided closer to a negative side of the first horizontal axis than the transfer mechanism;
a second storage shelf group provided closer to the positive side of the first horizontal axis than the transfer mechanism; and
a third storage shelf group provided closer to a positive side or a negative side of a second horizontal axis, which is perpendicular to the first horizontal axis, than the transfer mechanism,
wherein the first storage shelf group includes a plurality of first storage shelves configured to store the carrier,
wherein the second storage shelf group includes a plurality of second storage shelves configured to store the carrier,
wherein the third storage shelf group includes a plurality of third storage shelves configured to store the carrier,
wherein the plurality of second storage shelves are disposed to be arranged in two or more columns along the second horizontal axis and in two or more stages along a vertical axis,
wherein the plurality of third storage shelves are disposed to be arranged in two or more stages along the vertical axis, and each of the plurality of third storage shelves is movable along the vertical axis, and
wherein the transfer mechanism is configured to transfer the carrier to the plurality of first storage shelves, the plurality of second storage shelves, and the plurality of third storage shelves.

8. A carrier transfer method of transferring a carrier, which accommodates a plurality of substrates, in a carrier storage apparatus that stores the carrier,
wherein the carrier storage apparatus comprises:
a transfer mechanism configured to transfer the carrier;
a first storage shelf group provided closer to a negative side of a first horizontal axis than the transfer mechanism;
a second storage shelf group provided closer to a positive side of the first horizontal axis than the transfer mechanism; and
a third storage shelf group provided closer to a positive side or a negative side of a second horizontal axis, which is perpendicular to the first horizontal axis, than the transfer mechanism,
wherein the first storage shelf group includes a plurality of first storage shelves configured to store the carrier,
wherein the second storage shelf group includes a plurality of second storage shelves configured to store the carrier,
wherein the third storage shelf group includes a plurality of third storage shelves configured to store the carrier,
wherein the plurality of second storage shelves are disposed to be arranged in two or more columns along the second horizontal axis and in two or more stages along a vertical axis,
wherein the plurality of third storage shelves are disposed to be arranged in two or more stages along the vertical axis, and
wherein the carrier transfer method comprises:
moving the plurality of third storage shelves along the vertical axis; and
transferring, by the transfer mechanism, the carrier to the plurality of first storage shelves, the plurality of second storage shelves, and the plurality of third storage shelves.
